(19) United States
(12) Patent Application Publication
(10) Pub. No.: US 2024/0224692 A1
(43) Pub. Date: Jul. 4, 2024

(54) LIGHT EMITTING DISPLAY APPARATUS

(71) Applicant: LG Display Co., Ltd., Seoul (KR)

(72) Inventors: Pu-Reum KIM, Paju-si (KR); Yeon-Suk KANG, Paju-si (KR)

(73) Assignee: LG Display Co., Ltd., Seoul (KR)

(21) Appl. No.: 18/383,756

(22) Filed: Oct. 25, 2023

(30) Foreign Application Priority Data
Dec. 29, 2022 (KR) 10-2022-0189903

(51) Int. Cl. H10K 59/38; H10K 59/35; H10K 59/80

(52) U.S. Cl. CPC H10K 59/38; H10K 59/353; H10K 59/878; H10K 59/879; H10K 59/8792

(57) ABSTRACT

An organic light emitting diode display device can include first, second and third subpixels disposed on a substrate; first, second and third light emitting diodes disposed in the first, second and third subpixels, respectively; a black matrix disposed in boarder regions of the second subpixel and the third subpixel. Also, a first color filter is disposed in the first subpixel and overlapping with the first light emitting diode; and a transparent layer is disposed in at least one of the second and third subpixels between portions of the black matrix.

### CROSS REFERENCE TO RELATED APPLICATIONS

The present application claims priority to Korean Patent Application No. 10-2022-0189903 filed in Republic of Korea, on Dec. 29, 2022, which is incorporated herein by reference in its entirety into the present application.

### BACKGROUND

### Technical Field

The present disclosure relates to a display device, and more particularly, to an organic light emitting diode display device including a transparent layer and a color filter layer.

### Discussion of the Related Art

Recently, with the advent of an information-oriented society and as the interest in information displays for processing and displaying a massive amount of information and the demand for portable information media have increased, a display field has rapidly advanced. Thus, various lightweight and thin flat panel display devices have been developed and highlighted.

Among the various flat panel display devices, an organic light emitting diode (OLED) display device is an emissive type device, which does not include a backlight unit used in a non-emissive type device such as a liquid crystal display (LCD) device. As a result, the OLED display device is lightweight and has a thin profile, and has advantages in a viewing angle, a contrast ratio and a power consumption to be applied to various fields.

A head mounted display (HMD) including an organic light emitting display device has been recently developed. The HMD is a glass type monitor for virtual reality (VR) or augmented reality (AR) which is worn as a shape of a glass or a helmet such that a focus is formed at a point having a short distance away from a user's eyes.

The OLED display device having a small size and a high resolution applied to the HMD can be formed through a semiconductor process based on a wafer. In the semiconductor process, an anode is disposed on an insulating layer covering a thin film transistor on a wafer, and an emitting layer and a cathode are disposed on the anode. Further, an encapsulating layer, a color filter layer and a microlens array are sequentially disposed on the cathode.

In the HMD, light having excellent color purity and excellent color reproducibility is emitted from an open area due to a microcavity effect, and some unadjusted light is emitted from a non-open area, which reduces color purity and color reproducibility.

To solve the above problems, a color filter layer can be disposed on an encapsulating layer. The color filter layer absorbs light of a sub-peak of the non-open area to increase a color purity and a color reproducibility. However, a transmittance of the open area is reduced, which decreases efficiency and luminance. Also, subpixels that emit different colors of light may have different needs or different issues to address, in order to improve the color of light that is output. Thus, there exists a need for improving the amount of light and the color of light that is emitted by different subpixels.

### SUMMARY OF THE DISCLOSURE

Accordingly, embodiments of the present disclosure are directed to a display device that substantially obviates one or more of problems due to the limitations and disadvantages of the related art.

An object of the present disclosure is to provide an organic light emitting display device where a light of a sub-peak of a non-open area is blocked by disposing portions of a black matrix having different widths to correspond to a non-open area and disposing color filters to correspond to an open area, in which a color purity, a color reproducibility, an efficiency and a luminance are improved.

Another object of the present disclosure is to provide an organic light emitting diode display device where a light of a sub-peak of a non-open area is blocked by disposing portions of a black matrix having different widths to correspond to a non-open area and disposing a microlens to correspond to an open area, in which a color purity, a color reproducibility, an efficiency and a luminance are improved.

Additional features and advantages of the disclosure will be set forth in the description which follows, and in part will be apparent to those skilled in the art from the description or can be learned by practice of the disclosure. These and other advantages of the disclosure can be realized and attained by the structure particularly pointed out in, or derivable from, the written description, claims hereof, and the appended drawings.

To achieve these and other advantages and in accordance with the purpose of the present disclosure, as embodied and broadly described herein, an organic light emitting diode display device includes: a substrate having first, second and third subpixels; a light emitting diode in each of the first, second and third subpixels on the substrate; a black matrix in the second and third subpixels of a border region between the first, second and third subpixels on the light emitting diode; a first color filter in the first subpixel on the light emitting diode; and a transparent layer in at least one of the second and third subpixels between portions of the black matrix.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing an organic light emitting diode display device according to an embodiment of the present disclosure;

FIG. 2 is a plan view showing a display panel of an organic light emitting diode display device according to an embodiment of the present disclosure;

FIG. 3 is a cross-sectional view taken along a line III-III of FIG. 2 according to an embodiment of the present disclosure;

FIG. 4 is a view showing spectrums of lights emitted from open areas of red, green and blue subpixels of an organic light emitting diode display device according to an embodiment of the present disclosure;

FIG. 5 is a cross-sectional view showing a display panel of an organic light emitting diode display device according to an embodiment of the present disclosure;

FIG. 6 is a view showing spectrums of lights emitted from open areas of red, green and blue subpixels of an organic light emitting diode display device according to an embodiment of the present disclosure;

FIG. 7 is a cross-sectional view showing a display panel of an organic light emitting diode display device according to another embodiment of the present disclosure;

FIG. 8 is a cross-sectional view showing a display panel of an organic light emitting diode display device according to another embodiment of the present disclosure;

FIG. 9 is a cross-sectional view showing a display panel of an organic light emitting diode display device according to another embodiment of the present disclosure;

FIG. 10 is a cross-sectional view showing a display panel of an organic light emitting diode display device according to another embodiment of the present disclosure;

FIG. 11 is a cross-sectional view showing a display panel of an organic light emitting diode display device according to another embodiment of the present disclosure; and

FIG. 12 is a cross-sectional view showing a display panel of an organic light emitting diode display device according to another embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure can, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The features of various embodiments of the present disclosure can be partially or entirely coupled to or combined with each other and can be interlocked and operated in technically various ways, and the embodiments can be carried out independently of or in association with each other.

Hereinafter, an organic light emitting diode display device according to various example embodiments of the present disclosure will be described in detail with reference to the accompanying drawings.

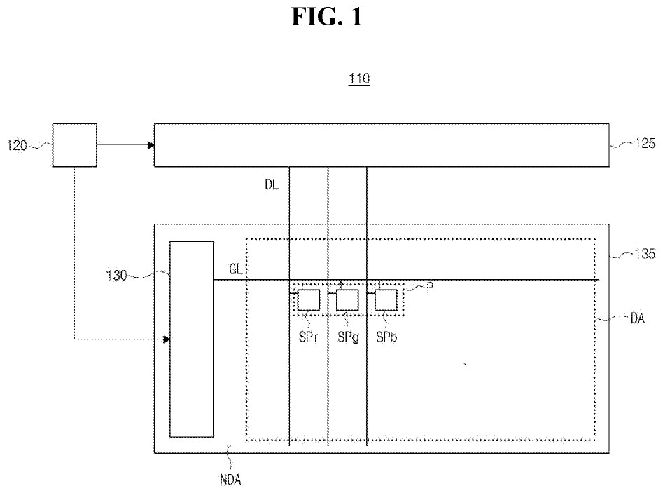

FIG. 1 is a view showing an organic light emitting diode display device according to a first embodiment of the present disclosure.

In FIG. 1, an organic light emitting diode (OLED) display device 110 according to a first embodiment of the present disclosure includes a timing controlling unit 120, a data driving unit 125, a gate driving unit 130 and a display panel 135.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 125 and transmits the gate control signal to the gate driving unit 130.

The data driving unit 125 generates a data signal (data voltage) using the data control signal and the image data transmitted from the timing controlling unit 120 and supplies the data signal to a data line DL of the display panel 135.

The gate driving unit 130 generates a gate signal (gate voltage) using the gate control signal transmitted from the timing controlling unit 120 and supplies the gate signal to a gate line GL of the display panel 135. In addition, the gate driving unit 130 can generate an emission signal according to a structure of each subpixel SPr, SPg and SPb and can supply the emission signal to the display panel 135.

The gate driving unit 130 can have a gate in panel (GIP) type to be formed in a non-display area NDA of a substrate of the display panel 135 having the gate line GL, the data line DL and a pixel P.

The display panel 135 includes a display area DA at a central portion thereof and a non-display area NDA surrounding the display area DA. The display panel 135 displays an image using the gate signal and the data signal. For displaying an image, the display panel 135 includes a plurality of pixels P, a plurality of gate lines GL and a plurality of data lines DL in the display area DA.

Each of the plurality of pixels P can include red, green and blue subpixels SPr, SPg and SPb. The gate line GL and the data line DL cross each other to define the red, green and blue subpixels SPr, SPg and SPb, and each of the red, green and blue subpixels SPr, SPg and SPb is connected to the gate line GL and the data line DL.

Also, each of the red, green and blue subpixels SPr, SPg and SPb can include a plurality of thin film transistors such as a switching thin film transistor and a driving thin film transistor, a storage capacitor and a light emitting diode.

A structure of the display panel 135 of the OLED display device 110 will be described with reference to a drawing.

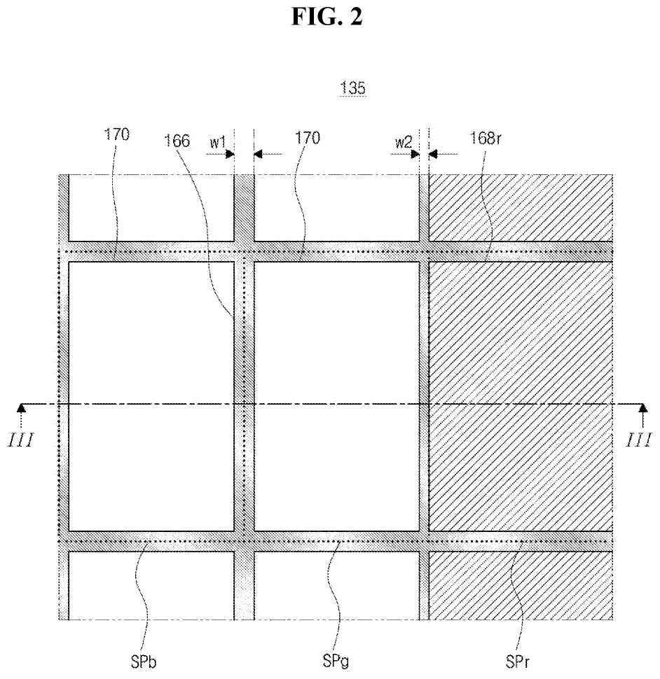

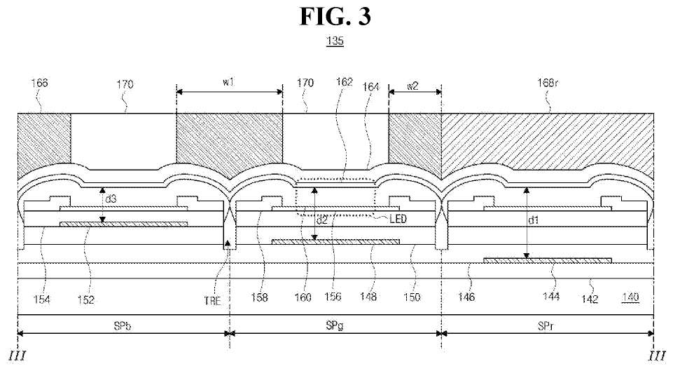

FIG. 2 is a plan view showing a display panel of an organic light emitting diode display device according to a first embodiment of the present disclosure, and FIG. 3 is a cross-sectional view taken along a line III-III of FIG. 2 according to an embodiment of the present disclosure.

In FIGS. 2 and 3, the display panel 135 of the OLED display device 110 according to a first embodiment of the present disclosure includes the red, green and blue subpixels SPr, SPg and SPb, and each of the red, green and blue subpixels SPr, SPg and SPb includes a plurality of thin film transistors and a light emitting diode LED. For example, the OLED display device 110 can have a top emission type.

The plurality of thin film transistors and a storage capacitor are disposed in each of the red, green and blue subpixels SPr, SPg and SPb on a substrate 140.

The substrate 140 can include a glass, a plastic or a semiconductor material. For example, the substrate 140 can be a wafer including single crystalline silicon.

The plurality of thin film transistors can include a switching thin film transistor, a driving thin film transistor and a sensing thin film transistor.

Also, the gate line GL (of FIG. 1) and the data line DL (of FIG. 1) connected to the switching thin film transistor, a power line connected to the driving thin film transistor, a sensing line and a reference line connected to the sensing thin film transistor can be disposed on the substrate 140.

The switching thin film transistor can be switched according to the gate signal of the gate line GL to transmit the data signal of the data line DL to the driving thin film transistor.

The driving thin film transistor can be switched according to the data signal through the switching thin film transistor to transmit a current due to a high level voltage of the power line to the light emitting diode LED.

The sensing thin film transistor can be switched according to a sensing signal of the sensing line to transmit a reference voltage to the driving thin film transistor or to detect a voltage of the driving thin film transistor.

The storage capacitor can store the data signal through the switching thin film transistor for one frame.

A first insulating layer 142 is disposed on the plurality of thin film transistors over the entire substrate 140, and a first reflecting layer 144 is disposed on the first insulating layer 142 in the red subpixel SPr.

A second insulating layer 146 is disposed on the first reflecting layer 144 over the entire substrate 140, and a second reflecting layer 148 is disposed on the second insulating layer 146 in the green subpixel SPg.

A third insulating layer 150 is disposed on the second reflecting layer 148 over the entire substrate 140, a third reflecting layer 152 is disposed on the third insulating layer 150 in the blue subpixel SPb, and a fourth insulating layer 154 is disposed on the third reflecting layer 152 over the entire substrate 140.

The first, second, third and fourth insulating layers 142, 146, 150 and 154 generate a microcavity effect by adjusting distances from a second electrode 162 to the first, second and third reflecting layers 144, 148 and 152. For example, the first reflecting layer 144, the second reflecting layer 148 and the third reflecting layer 152 can be disposed on different layers and located a different distances away from the corresponding emitting layer.

For example, each of the first, second, third and fourth insulating layers 142, 146, 150 and 154 can include an inorganic insulating material such as silicon oxide SiOx and silicon nitride SiNx or an organic insulating material such as acrylic resin, epoxy resin, phenolic resin, polyamide resin and polyimide resin and can have a single layer or a multiple layer.

The first, second and third reflecting layers 144, 148 and 152 reflect a light emitted from an emitting layer 160 or a light reflected on the second electrode 162 toward the second electrode 162. The first, second and third reflecting layers 144, 148 and 152 can be floated or can be connected between the driving thin film transistor and a first electrode 156.

For example, each of the first, second and third reflecting layers 144, 148 and 152 can include silver (Ag) or a metallic material having silver (Ag).

The first electrode 156 is disposed on the fourth insulating layer 154 in each of the red, green and blue subpixels SPr, SPg and SPb.

The first electrode 156 can be connected to the driving thin film transistor through a contact hole. Alternatively, the first electrode 156 of the red subpixel SPr can be connected to the first reflecting layer 144 through a contact hole in the second, third and fourth insulating layers 146, 150 and 154, and the first reflecting layer 144 can be connected to the driving thin film transistor through a contact hole in the first insulating layer 142. The first electrode 156 of the green subpixel SPg can be connected to the second reflecting layer 148 through a contact hole in the third and fourth insulating layers 150 and 154, and the second reflecting layer 148 can be connected to the driving thin film transistor through a contact hole in the first and second insulating layers 142 and 146. The first electrode 156 of the blue subpixel SPb can be connected to the third reflecting layer 152 through a contact hole in the fourth insulating layer 154, and the third reflecting layer 152 can be connected to the driving thin film transistor through a contact hole in the first, second and third insulating layers 142, 146 and 150.

For example, the first electrode 156 can be an anode and can include a transparent conductive material or a half transmissive material.

A bank layer 158 is disposed on the first electrode 156, and a trench TRE is formed in the bank layer 158 and the second, third and fourth insulating layers 146, 150 and 154 at a border region between the red, green and blue subpixels SPr, SPg and SPb. For example, the trench TRE can be located between adjacent subpixels.

The bank layer 158 covers an edge portion of the first electrode 156 and has an opening exposing a central portion of the first electrode 156. The central portion of the first electrode 156 exposed through the opening of the bank layer 158 (a portion corresponding to the opening of the bank layer 158) can be defined as an open area (an emission area), and the other portion except for the open area in each subpixel can be defined as a non-open area (a non-emission area).

Although the bank layer 158 is disposed to expose the trench TRE in a first embodiment of FIGS. 2 and 3, the bank layer 158 can be consecutively disposed between the adjacent subpixels to cover the trench TRE.

For example, the bank layer 158 can include an inorganic insulating material such as silicon oxide (SiOx) and silicon nitride (SiNx) or an organic insulating material such as acrylic resin, epoxy resin, phenolic resin, polyamide resin and polyimide resin and can have a single layer or a multiple layer.

The trench TRE can divide or separate the emitting layer 160 of adjacent subpixels in a subsequent process to minimize or reduce a lateral leakage current.

The emitting layer 160 is disposed on the bank layer 158 and the first electrode 156 exposed through the opening of the bank layer 158. The emitting layer 160 can have a single stack or a first stack, a charge generating layer and a second stack.

When the emitting layer 160 has a single stack, the single stack can include a hole injecting layer (HIL), a hole transporting layer (HTL), an emitting material layer (EML), an electron transporting layer (ETL) and an electron injecting layer (EIL).

When the emitting layer 160 has a first stack, a charge generating layer and a second stack, the first stack can include a hole injecting layer, a hole transporting layer, an emitting material layer and an electron transporting layer, and the emitting material layer of the first stack can emit one of a red colored light, a green colored light, a blue colored light and a yellow colored light.

The charge generating layer can include a negative type charge generating layer for supplying an electron to the first stack and a positive type charge generating layer for supplying a hole to the second stack.

The second stack can include a hole transporting layer, an emitting material layer, an electron transporting layer and an electron injecting layer, and the emitting material layer of the second stack can emit one of a red colored light, a green colored light, a blue colored light and a yellow colored light.

The emitting material layer of the second stack can emit a light of a color different from a color of a light emitted from the emitting material layer of the first stack. For example, the emitting material layer of the first stack can emit a blue colored light and the emitting material layer of the second stack can emit a yellow colored light. Alternatively, the emitting material layer of the first stack can emit a blue colored light and the emitting material layer of the second stack can emit a red colored light and a green colored light.

The second electrode 162 and the encapsulating layer 164 are sequentially disposed on the emitting layer 160 over the entire substrate 150.

For example, the second electrode 162 can be a cathode and can include a transparent conductive material and a half transmissive metallic material.

The first electrode 156, the emitting layer 160 and the second electrode 162 constitute a light emitting diode LED. A light emitted from the emitting layer 160 can be reflected between the second electrode 162 and the first, second and third reflecting layers 144, 148 and 152 to be constructively interfered and then can be emitted toward an exterior through the second electrode 162.

Due to the first, second, third and fourth insulating layers 142, 146, 150 and 154, a first distance d1 between the second electrode 162 and the first reflecting layer 144 in the red subpixel SPr is greater than a second distance d2 between the second electrode 162 and the second reflecting layer 148 in the green subpixel SPg, and the second distance d2 between the second electrode 162 and the second reflecting layer 148 in the green subpixel SPg is greater than a third distance d3 between the second electrode 162 and the third reflecting layer 152 in the blue subpixel SPb (e.g., d1>d2>d3). As a result, a light extraction efficiency of the red colored light, the green colored light and the blue colored light in the open areas of the red subpixel SPr, the green subpixel SPg and the blue subpixel SPb can be improved due to a micro cavity effect.

The encapsulating layer 164 can block moisture and oxygen of an exterior.

The encapsulating layer 164 can have a single layer of an inorganic insulating material or a multiple layer of an inorganic insulating material and an organic insulating material. When the encapsulating layer 164 has a multiple layer, the encapsulating layer 164 can include an inorganic insulating material layer, an organic insulating material layer and an inorganic insulating material layer sequentially disposed on the second electrode 162.

For example, the encapsulating layer 164 can include an inorganic insulating material such as silicon oxide (SiOx) and silicon nitride (SiNx) or an organic insulating material such as acrylic resin and epoxy resin.

A portion of the emitting layer 160 can be divided over the trench TRE or the emitting layer 160 can be completely disconnected over the trench, due to a step difference of the trench TRE such that the emitting layers 160 of the red, green and blue subpixels SPr, SPg and SPb do not contact each other and are spaced apart from each other.

Further, the second electrode 162 may not be divided over the trench TRE even by the step difference of the trench TRE such that the second electrodes 162 of the red, green and blue subpixels SPr, SPg and SPb are connected to each other.

For example, a thickness of the emitting layer 160 can be reduced from a top portion of a sidewall of the trench TRE to the substrate such that the emitting layer 160 is cut in the trench TRE.

In the OLED display device 110 according to a first embodiment of the present disclosure, the emitting layers 160 of the adjacent two of the red, green and blue subpixels SPr, SPg and SPb are divided over the trench TRE to be separated from each other. As a result, a lateral leakage current between the adjacent two of the red, green and blue subpixels SPr, SPg and SPb emitting a light of the different colors can be reduced or minimized. In this way, the trench TRE can prevent or block current leakage between two adjacent subpixels.

A black matrix 166 is disposed in a border region between the red, green and blue subpixels SPr, SPg and SPb on the encapsulating layer 164. The black matrix 166 is disposed to correspond to the non-open area of the green and blue subpixels SPg and SPb and the black matrix 166 has a matrix shape covering an edge portion of each of the green and blue subpixels SPg and SPb and exposing the entire red subpixel SPr and a central portion of each of the green and blue subpixels SPg and SPb.

The black matrix 166 is not disposed in the red subpixel SPr of the border region between the red and green subpixels SPr and SPg and is disposed in the green subpixel SPg of the border region between the red and green subpixels SPr and SPg. In other words, the black matrix 166 can be located between a center of the trench TRE and the green subpixel SPg, but the area between the center of the trench TRE and the red subpixel SPr does not include any portion of the black matrix 166. The black matrix 166 is disposed in the green and blue subpixels SPg and SPb of the border region between the green and blue subpixels SPg and SPb. The black matrix 166 is disposed in the blue subpixel SPb of the border region between the blue and red subpixels SPb and SPr and is not disposed in the red subpixel SPr of the border region between the blue and red subpixels SPb and SPr.

The black matrix 166 is not disposed in the red subpixel SPr and is disposed in the green and blue subpixels SPg and SPb. As a result, a first width w1 of the black matrix 166 between the green and blue subpixels SPg and SPb can be greater than a second width w2 of the black matrix 166 between the red and green subpixels SPr and SPg and between the blue and red subpixels SPb and SPr (e.g., w1>w2).

For example, the black matrix 166 can include an organic insulating material or an inorganic insulating material having a relatively high absorbance and a relatively low transmittance, or the black matrix 166 can include an opaque metallic material such as molybdenum (Mo) and titanium (Ti).

A red color filter 168r is disposed on the encapsulating layer 164 in the red subpixel SPr, and a transparent layer 170 is disposed on the encapsulating layer 164 in each of the green and blue subpixels SPg and SPb between portions of the black matrix 166.

The red color filter 168r is disposed to correspond to the red subpixel SPr, and the transparent layer 170 is disposed to correspond to the open area of each of the green and blue subpixels SPg and SPb.

For example, the red color filter 168r can include an organic material having a red pigment or a red dye and a relatively high transmittance, and the transparent layer 170 can include an organic material having a relatively high transmittance.

The black matrix 166, the red color filter 168r and the transparent layer 170 can have substantially the same thickness.

In the OLED display device 110 according to a first embodiment of the present disclosure, a light extraction efficiency of the open area of the red, green and blue subpixels SPr, SPg and SPb is improved due to a microcavity effect according to adjustment of the distances between the first, second and third reflecting layers 144, 148 and 152 and the second electrode 162.

Since the second distance d2 between the second electrode 162 and the second reflecting layer 148 in the green subpixel SPg is greater than the third distance d3 between the second electrode 162 and the third reflecting layer 152 in the blue subpixel SPb and is smaller than the first distance d1 between the second electrode 162 and the first reflecting layer 144 in the red subpixel SPr (e.g., d1>d2>d3), the red colored light, the green colored light and the blue colored light of the emitting layer 160 are reflected between the second electrode 162 and the first, second and third reflecting layers 144, 148 and 152 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open area of the green and blue subpixels SPg and SPb have green and blue main peaks corresponding to green and blue colors, respectively.

Since the red color filter 168r is disposed in the open area of the red subpixel SPr, the light of the red main peak corresponding to a red color passes through the red color filter 168r and the light of the red sub-peak corresponding to a color other than a red color is absorbed or blocked by the red color filter 168r such that a color purity is improved. For example, the red color filter 168r can filter out the light of the red sub-peak corresponding to a color other than a red color. Since the transparent layer 170 is disposed in the open area of each of the green and blue subpixels SPg and SPb instead of green and blue color filters, the light of the green and blue main peaks corresponding to green and blue colors pass through the transparent layer 170 without a loss such that luminance is improved. In other words, the red subpixel SPr can include a color filter, while the green and blue subpixels SPg and SPb do not include any color filters.

Among the lights emitted from the open area and the non-open area of the red subpixel SPr, the light of the red main peak corresponding to a red color passes through the red color filter 168r to be emitted to an exterior, and the light of the red sub-peak corresponding to a color other than a red color is absorbed by the red color filter 168r not to be emitted to an exterior. The light emitted from the non-open areas of the green and blue subpixels SPg and SPb is absorbed by the black matrix 166 not to be emitted to an exterior.

As a result, the lights of the sub-peaks of the non-open areas of the red, green and blue subpixels SPr, SPg and SPb are blocked, and a color purity and a color reproducibility are improved.

The light emitted from the red, green and blue subpixels due to a microcavity will be described with reference to a drawing.

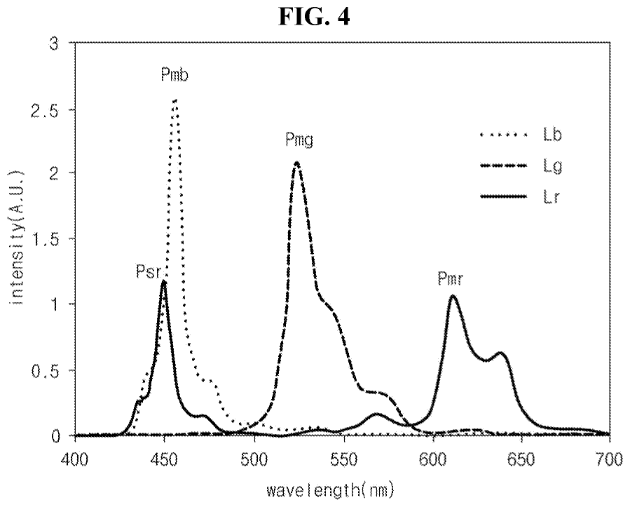

FIG. 4 is a view showing spectrums of lights emitted from open areas of red, green and blue subpixels of an organic light emitting diode display device according to a first embodiment of the present disclosure.

In FIG. 4, a red light Lr emitted through the second electrode 162 of the open area of the red subpixel SPr of the OLED display device 110 according to a first embodiment of the present disclosure has a red main peak Pmr corresponding to a red color and a red sub-peak Psr corresponding to a color other than a red color (for example, a blue color). A green light Lg and a blue light Lb emitted through the second electrodes 162 of the open areas of the green subpixel SPg and the blue subpixel SPb of the OLED display device 110 according to a first embodiment of the present disclosure have a green main peak Pmg and a blue main peak Pmb, respectively, and do not have a green sub-peak and a blue sub-peak corresponding to a color other than a green color and a blue color.

In the OLED display device 110 according to a first embodiment of the present disclosure, since the red color filter 168r of the open area of the red subpixel SPr transmits the light of the red main peak Pmr corresponding to a red color and absorbs or blocks the light of the red sub-peak Psr corresponding to a color other than a red color, a color purity of the red subpixel SPr is improved (e.g., a purer and truer red can be provided). Further, since the transparent layers 170 of the open areas of the green and blue subpixels SPg and SPb transmit the lights of the green and blue main peaks Pmg and Pmb corresponding to green and blue colors without a loss, a luminance is improved.

In another embodiment, a blue color filter can be disposed in the blue subpixel.

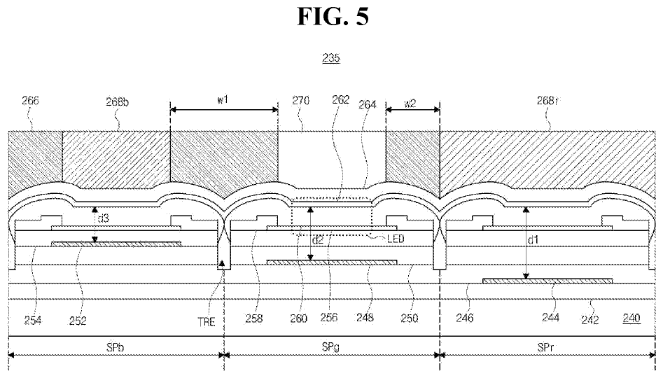

FIG. 5 is a cross-sectional view showing a display panel of an organic light emitting diode display device according to a second embodiment of the present disclosure. Illustration on a part of a second embodiment the same as that of a first embodiment can be omitted.

In FIG. 5, a display panel 235 of an organic light emitting diode display device according to a second embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 242, a first reflecting layer 244, a second insulating layer 246, a second reflecting layer 248, a third insulating layer 250, a third reflecting layer 252, a fourth insulating layer 254, a first electrode 256, a bank layer 258, an emitting layer 260, a second electrode 262 and an encapsulating layer 264 are sequentially disposed on a substrate 240.

A black matrix 266 is disposed in a border region between the red, green and blue subpixels SPr, SPg and SPb on the encapsulating layer 264. The black matrix 266 is disposed to correspond to a non-open area of the green and blue subpixels SPg and SPb and the black matrix 266 has a matrix shape covering an edge portion of each of the green and blue subpixels SPg and SPb and exposing the entire red subpixel SPr and a central portion of each of the green and blue subpixels SPg and SPb.

The black matrix 266 is not disposed in the red subpixel SPr of the border region between the red and green subpixels SPr and SPg and is disposed in the green subpixel SPg of the border region between the red and green subpixels SPr and SPg. The black matrix 266 is disposed in the green and blue subpixels SPg and SPb of the border region between the green and blue subpixels SPg and SPb. The black matrix 266 is disposed in the blue subpixel SPb of the border region between the blue and red subpixels SPb and SPr and is not disposed in the red subpixel SPr of the border region between the blue and red subpixels SPb and SPr. In other words, the black matrix 266 can be located between a center of the trench TRE and the green subpixel SPg, but the area between the trench TRE and the red subpixel SPr does not include any portion of the black matrix 266.

The black matrix 266 is not disposed in the red subpixel SPr and is disposed in the green and blue subpixels SPg and SPb. As a result, a first width w1 of the black matrix 266 between the green and blue subpixels SPg and SPb can be greater than a second width w2 of the black matrix 266 between the red and green subpixels SPr and SPg and between the blue and red subpixels SPb and SPr (e.g., w1>w2).

For example, the black matrix 266 can include an organic insulating material or an inorganic insulating material having a relatively high absorbance and a relatively low transmittance, or the black matrix 266 can include an opaque metallic material such as molybdenum (Mo) and titanium (Ti).

Red and blue color filters 268r and 268b are disposed on the encapsulating layer 264 in the red and blue subpixels SPr and SPb, respectively, and a transparent layer 270 is disposed on the encapsulating layer 264 in the green subpixels SPg between portions of the black matrix 266.

The red and blue color filters 268r and 268b are disposed to correspond to the red and blue subpixels SPr and SPb, respectively, and the transparent layer 270 is disposed to correspond to an open area of the green subpixel SPg.

For example, the red and blue color filters 268r and 268b can include an organic material having red and blue pigments or red and blue dyes, respectively, and a relatively high transmittance, and the transparent layer 270 can include an organic material having a relatively high transmittance.

The black matrix 266, the red and blue color filters 268r and 268b and the transparent layer 270 can have substantially the same thickness.

In the OLED display device according to a second embodiment of the present disclosure, a light extraction efficiency of the open area of the red, green and blue subpixels SPr, SPg and SPb is improved due to a microcavity effect according to adjustment of the distances between the first, second and third reflecting layers 244, 248 and 252 and the second electrode 262.

Since the second distance d2 between the second electrode 262 and the second reflecting layer 248 in the green subpixel SPg is greater than the third distance d3 between the second electrode 262 and the third reflecting layer 252 in the blue subpixel SPb and is smaller than the first distance d1 between the second electrode 262 and the first reflecting layer 244 in the red subpixel SPr (e.g., d1>d2>d3), the red colored light, the green colored light and the blue colored light of the emitting layer 260 are reflected between the second electrode 262 and the first, second and third reflecting layers 244, 248 and 252 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open areas of the red and blue subpixels SPr and SPb have red and blue main peaks corresponding to red and blue colors, respectively, and red and blue sub-peaks corresponding to a color other than the red and blue colors, while the light emitted from the open area of the green subpixel SPg has a green main peak corresponding to a green color.

Since the red and blue color filters 268r and 268b are disposed in the open areas of the red and blue subpixels SPr and SPb, respectively, the lights of the red and blue main peaks corresponding to red and blue colors pass through the red and blue color filters 268r and 268b, respectively, and the lights of the red and blue sub-peaks corresponding to a color other than red and blue colors are absorbed by the red and blue color filters 268r and 268b, respectively, such that a color purity is improved. Since the transparent layer 270 is disposed in the open area of the green subpixel SPg instead of a green color filter, the light of the green main peak corresponding to a green color passes through the transparent layer 270 without a loss such that a luminance is improved. For example, the red and blue subpixels SPr and SPb can include corresponding color filters, while the green subpixel SPg does not include any color filter.

Among the lights emitted from the open area and the non-open area of the red subpixel SPr, the light of the red main peak corresponding to a red color passes through the red color filter 268r to be emitted to an exterior, and the light of the red sub-peak corresponding to a color other than a red color is blocked or absorbed by the red color filter 268r not to be emitted to an exterior. The lights emitted from the non-open areas of the green and blue subpixels SPg and SPb are absorbed by the black matrix 266 not to be emitted to an exterior.

As a result, the lights of the sub-peaks of the non-open areas of the red, green and blue subpixels SPr, SPg and SPb are blocked, and a color purity and a color reproducibility are improved.

The light emitted from the red, green and blue subpixels due to a microcavity will be illustrated with reference to a drawing.

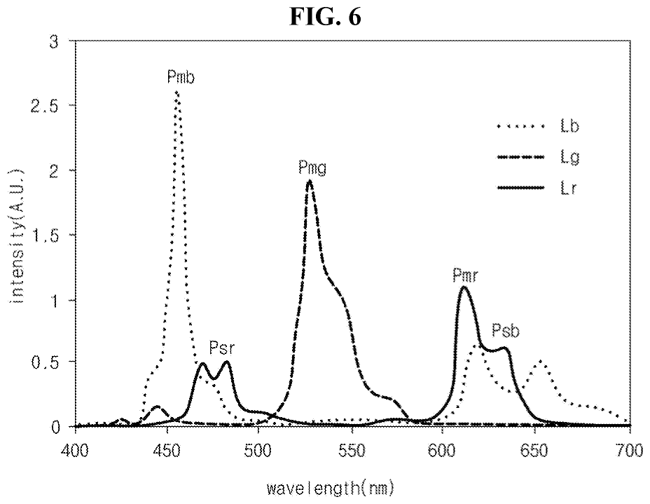

FIG. 6 is a view showing spectrums of lights emitted from open areas of red, green and blue subpixels of an organic light emitting diode display device according to a second embodiment of the present disclosure.

In FIG. 6, red and blue lights Lr and Lb emitted through the second electrodes 262 of the open areas of the red and blue subpixels SPr and SPb of the OLED display device according to a second embodiment of the present disclosure have red and blue main peaks Pmr and Pmb corresponding to red and blue colors, respectively, and red and blue sub-peaks Psr and Psb corresponding to a color other than red and blue colors (for example, blue and red colors), respectively. A green light Lg emitted through the second electrode 262 of the open area of the green subpixel SPg of the OLED display device according to a second embodiment of the present disclosure has a green main peak Pmg and does not have a green sub-peak corresponding to a color other than a green color.

In the OLED display device according to a second embodiment of the present disclosure, since the red and blue color filters 268r and 268b of the open areas of the red and blue subpixels SPr and SPb transmit the lights of the red and blue main peaks Pmr and Pmb corresponding to red and blue colors, respectively, and absorb or block the lights of the red and blue sub-peaks Psr and Psb corresponding to a color other than red and blue colors, respectively, a color purity of the red and blue subpixels SPr and SPb is improved. Further, since the transparent layer 270 of the open area of the green subpixel SPg transmits the light of the green main peak Pmg corresponding to a green color without a loss, a luminance is improved.

In another embodiment, a black matrix can be disposed in the red subpixel.

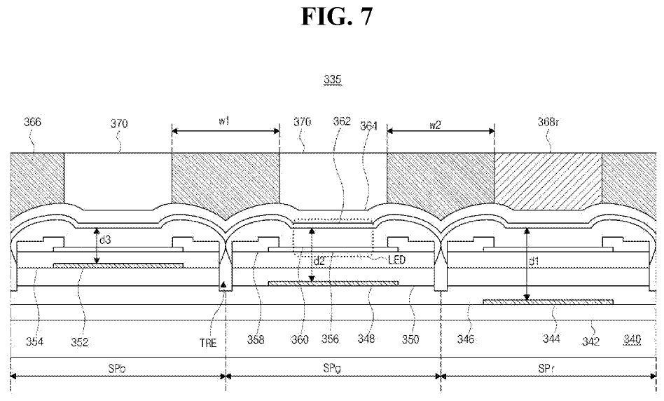

FIG. 7 is a cross-sectional view showing a display panel of an organic light emitting diode display device according to a third embodiment of the present disclosure. Illustration on a part of a third embodiment the same as that of first and second embodiments can be omitted.

In FIG. 7, a display panel 335 of an organic light emitting diode display device according to a third embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 342, a first reflecting layer 344, a second insulating layer 346, a second reflecting layer 348, a third insulating layer 350, a third reflecting layer 352, a fourth insulating layer 354, a first electrode 356, a bank layer 358, an emitting layer 360, a second electrode 362 and an encapsulating layer 364 are sequentially disposed on a substrate 340.

A black matrix 366 is disposed in a border region between the red, green and blue subpixels SPr, SPg and SPb on the encapsulating layer 364. The black matrix 366 is disposed to correspond to a non-open area of the red, green and blue subpixels SPr, SPg and SPb and the black matrix 366 has a matrix shape covering an edge portion of each of the red, green and blue subpixels SPr, SPg and SPb and exposing a central portion of each of the red, green and blue subpixels SPr, SPg and SPb.

The black matrix 366 is disposed in the red and green subpixels SPr and SPg of the border region between the red and green subpixels SPr and SPg. The black matrix 366 is disposed in the green and blue subpixels SPg and SPb of the border region between the green and blue subpixels SPg and SPb. The black matrix 366 is disposed in the blue and red subpixels SPb and SPr of the border region between the blue and red subpixels SPb and SPr.

The black matrix 366 is disposed in the red, green and blue subpixels SPr, SPg and SPb. As a result, a first width w1 of the black matrix 366 between the green and blue subpixels SPg and SPb can be the same as a second width w2 of the black matrix 366 between the red and green subpixels SPr and SPg and between the blue and red subpixels SPb and SPr (e.g., w1=w2). In other words, according to an embodiment, the black matrix 366 can be evenly distributed in the areas between the red, green and blue subpixels SPr, SPg and SPb.

For example, the black matrix 366 can include an organic insulating material or an inorganic insulating material having a relatively high absorbance and a relatively low transmittance, or the black matrix 366 can include an opaque metallic material such as molybdenum (Mo) and titanium (Ti).

A red color filter 368r is disposed on the encapsulating layer 364 in the red subpixel SPr, and a transparent layer 370 is disposed on the encapsulating layer 364 in each of the green and blue subpixels SPg and SPb between portions of the black matrix 366.

The red color filter 368r is disposed to correspond to the red subpixel SPr, and the transparent layer 370 is disposed to correspond to an open area of the green and blue subpixels SPg and SPb.

For example, the red color filter 368r can include an organic material having a red pigment or a red dye and a relatively high transmittance, and the transparent layer 370 can include an organic material having a relatively high transmittance.

The black matrix 366, the red color filter 368r and the transparent layer 370 can have substantially the same thickness.

In the OLED display device according to a third embodiment of the present disclosure, a light extraction efficiency of the open area of the red, green and blue subpixels SPr, SPg and SPb is improved due to a microcavity effect according to adjustment of the distances between the first, second and third reflecting layers 344, 348 and 352 and the second electrode 362.

Since the second distance d2 between the second electrode 362 and the second reflecting layer 348 in the green subpixel SPg is greater than the third distance d3 between the second electrode 362 and the third reflecting layer 352 in the blue subpixel SPb and is smaller than the first distance d1 between the second electrode 362 and the first reflecting layer 344 in the red subpixel SPr (e.g., d1>d2>d3), the red colored light, the green colored light and the blue colored light of the emitting layer 360 are reflected between the second electrode 362 and the first, second and third reflecting layers 344, 348 and 352 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 368r is disposed in the open area of the red subpixel SPr, the light of the red main peak corresponding to a red color passes through the red color filter 368r, and the light of the red sub-peak corresponding to a color other than a red color is absorbed by the red color filter 368r such that a color purity is improved. Since the transparent layer 370 is disposed in the open area of each of the green and blue subpixels SPg and SPb instead of green and blue color filters, the lights of the green and blue main peaks corresponding to green and blue colors pass through the transparent layer 370 without a loss such that a luminance is improved.

The lights emitted from the non-open areas of the red, green and blue subpixels SPr, SPg and SPb are blocked or absorbed by the black matrix 366 not to be emitted to an exterior.

As a result, the lights of the sub-peaks of the non-open areas of the red, green and blue subpixels SPr, SPg and SPb are blocked, and a color purity and a color reproducibility are improved (e.g., purer reds, greens and blues can be provided).

In another embodiment, a transparent layer can be used as a planarizing layer.

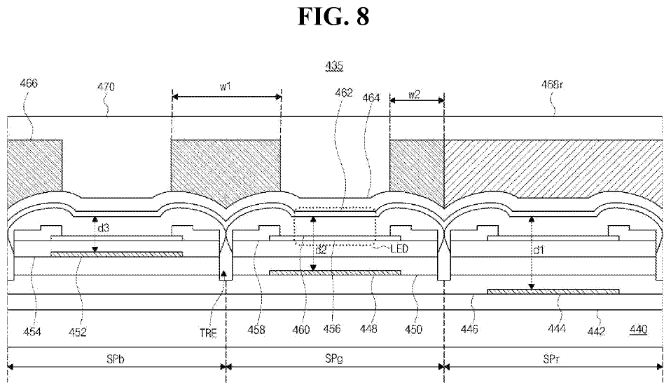

FIG. 8 is a cross-sectional view showing a display panel of an organic light emitting diode display device according to a fourth embodiment of the present disclosure. Illustration on a part of a fourth embodiment the same as that of first to third embodiments can be omitted.

In FIG. 8, a display panel 435 of an organic light emitting diode display device according to a fourth embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 442, a first reflecting layer 444, a second insulating layer 446, a second reflecting layer 448, a third insulating layer 450, a third reflecting layer 452, a fourth insulating layer 454, a first electrode 456, a bank layer 458, an emitting layer 460, a second electrode 462 and an encapsulating layer 464 are sequentially disposed on a substrate 440.

A black matrix 466 is disposed in a border region between the red, green and blue subpixels SPr, SPg and SPb on the encapsulating layer 464. The black matrix 466 is disposed to correspond to a non-open area of the green and blue subpixels SPg and SPb and the black matrix 466 has a matrix shape covering an edge portion of each of the green and blue subpixels SPg and SPb and exposing the entire red subpixel SPr and a central portion of each of the green and blue subpixels SPg and SPb.

The black matrix 466 is not disposed in the red subpixel SPr of the border region between the red and green subpixels SPr and SPg and is disposed in the green subpixel SPg of the border region between the red and green subpixels SPr and SPg. The black matrix 466 is disposed in the green and blue subpixels SPg and SPb of the border region between the green and blue subpixels SPg and SPb. The black matrix 466 is disposed in the blue subpixel SPb of the border region between the blue and red subpixels SPb and SPr and is not disposed in the red subpixel SPr of the border region between the blue and red subpixels SPb and SPr. In other words, the black matrix 466 can be located between a center of the trench TRE and the green subpixel SPg, but the area between the center of the trench TRE and the red subpixel SPr does not include any portion of the black matrix 466.

The black matrix 466 is not disposed in the red subpixel SPr and is disposed in the green and blue subpixels SPg and SPb. As a result, a first width w1 of the black matrix 466 between the green and blue subpixels SPg and SPb can be greater than a second width w2 of the black matrix 466 between the red and green subpixels SPr and SPg and between the blue and red subpixels SPb and SPr (w1>w2).

For example, the black matrix 466 can include an organic insulating material or an inorganic insulating material having a relatively high absorbance and a relatively low transmittance, or the black matrix 466 can include an opaque metallic material such as molybdenum (Mo) and titanium (Ti).

A red color filter 468r is disposed on the encapsulating layer 464 in the red subpixel SPr, and a transparent layer 470 is disposed on the encapsulating layer 464 in each of the green and blue subpixels SPg and SPb between portions of the black matrix 466. The transparent layer 470 covers and planarizes the red color filter 468r and the black matrix 466.

The black matrix 466 and the red color filter 468r can have substantially the same thickness as each other, and the transparent layer 470 can have a thickness greater than a thickness of each of the black matrix 466 and the red color filter 468r.

The red color filter 468r is disposed to correspond to the red subpixel SPr, and the transparent layer 470 is disposed to correspond to an open area of the green and blue subpixels SPg and SPb.

For example, the red color filter 468r can include an organic material having a red pigment or a red dye and a relatively high transmittance, and the transparent layer 470 can include an organic material having a relatively high transmittance.

In the OLED display device according to a fourth embodiment of the present disclosure, a light extraction efficiency of the open area of the red, green and blue subpixels SPr, SPg and SPb is improved due to a microcavity effect according to adjustment of the distances between the first, second and third reflecting layers 444, 448 and 452 and the second electrode 462.

Since the second distance d2 between the second electrode 462 and the second reflecting layer 448 in the green subpixel SPg is greater than the third distance d3 between the second electrode 462 and the third reflecting layer 452 in the blue subpixel SPb and is smaller than the first distance d1 between the second electrode 462 and the first reflecting layer 444 in the red subpixel SPr (e.g., d1>d2>d3), the red colored light, the green colored light and the blue colored light of the emitting layer 460 are reflected between the second electrode 462 and the first, second and third reflecting layers 444, 448 and 452 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 468r is disposed in the open area of the red subpixel SPr, the light of the red main peak corresponding to a red color passes through the red color filter 468r, and the light of the red sub-peak corresponding to a color other than a red color is blocked or absorbed by the red color filter 468r such that a color purity is improved. Since the transparent layer 470 is disposed in the open area of each of the green and blue subpixels SPg and SPb instead of green and blue color filters, the lights of the green and blue main peaks corresponding to green and blue colors pass through the transparent layer 470 without a loss such that a luminance is improved.

Among the lights emitted from the open area and the non-open area of the red subpixel SPr, the light of the red main peak corresponding to a red color passes through the red color filter 468r to be emitted to an exterior, and the light of the red sub-peak corresponding to a color other than a red color is absorbed by the red color filter 468r not to be emitted to an exterior. The lights emitted from the non-open areas of the green and blue subpixels SPg and SPb are absorbed by the black matrix 466 not to be emitted to an exterior.

As a result, the lights of the sub-peaks of the non-open areas of the red, green and blue subpixels SPr, SPg and SPb are blocked, and a color purity and a color reproducibility are improved.

Since the transparent layer 470 has a thickness greater than a thickness of the red color filter 468r and the black matrix 466 to planarize the red color filter 468r and the black matrix 466, a subsequent process is easily performed. For example, the transparent layer 470 can extend across the red, green and blue subpixels SPr, SPg and SPb, and includes protrusion portions that extend into the blue and green subpixels SPb and SPg to fill the corresponding holes in the black matrix 466.

In another embodiment, a microlens can be disposed on a transparent layer.

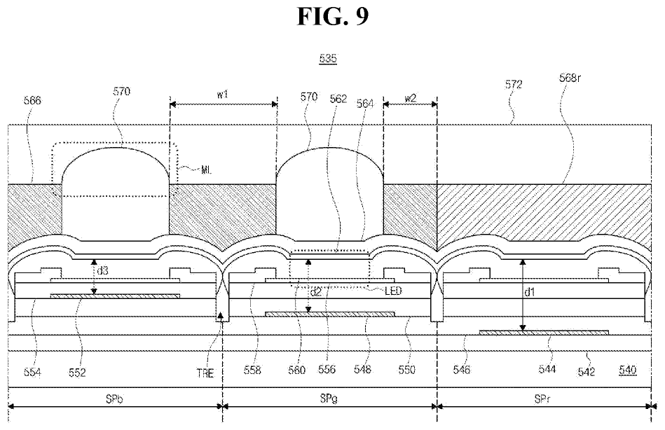

FIG. 9 is a cross-sectional view showing a display panel of an organic light emitting diode display device according to a fifth embodiment of the present disclosure. Illustration on a part of a fifth embodiment the same as that of first to fourth embodiments can be omitted.

In FIG. 9, a display panel 535 of an organic light emitting diode display device according to a fifth embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 542, a first reflecting layer 544, a second insulating layer 546, a second reflecting layer 548, a third insulating layer 550, a third reflecting layer 552, a fourth insulating layer 554, a first electrode 556, a bank layer 558, an emitting layer 560, a second electrode 562 and an encapsulating layer 564 are sequentially disposed on a substrate 540.

A black matrix 566 is disposed in a border region between the red, green and blue subpixels SPr, SPg and SPb on the encapsulating layer 564. The black matrix 566 is disposed to correspond to a non-open area of the green and blue subpixels SPg and SPb and the black matrix 566 has a matrix shape covering an edge portion of each of the green and blue subpixels SPg and SPb and exposing the entire red subpixel SPr and a central portion of each of the green and blue subpixels SPg and SPb.

The black matrix 566 is not disposed in the red subpixel SPr of the border region between the red and green subpixels SPr and SPg and is disposed in the green subpixel SPg of the border region between the red and green subpixels SPr and SPg. The black matrix 566 is disposed in the green and blue subpixels SPg and SPb of the border region between the green and blue subpixels SPg and SPb. The black matrix 566 is disposed in the blue subpixel SPb of the border region between the blue and red subpixels SPb and SPr and is not disposed in the red subpixel SPr of the border region between the blue and red subpixels SPb and SPr.

The black matrix 566 is not disposed in the red subpixel SPr and is disposed in the green and blue subpixels SPg and SPb. As a result, a first width w1 of the black matrix 566 between the green and blue subpixels SPg and SPb can be greater than a second width w2 of the black matrix 566 between the red and green subpixels SPr and SPg and between the blue and red subpixels SPb and SPr (e.g., w1>w2).

For example, the black matrix 566 can include an organic insulating material or an inorganic insulating material having a relatively high absorbance and a relatively low transmittance, or the black matrix 566 can include an opaque metallic material such as molybdenum (Mo) and titanium (Ti).

A red color filter 568r is disposed on the encapsulating layer 564 in the red subpixel SPr, and a transparent layer 570 is disposed on the encapsulating layer 564 in each of the green and blue subpixels SPg and SPb between portions of the black matrix 566. A microlens ML of a semispherical shape having a diameter the same as a width of the transparent layer 570 is disposed on a top surface of the transparent layer 570 as one body integrated with the transparent layer 570.

A light passing through the transparent layer 570 is concentrated on a front of the display panel 535 due to the microlens ML of the transparent layer 570 to improve a luminance.

A planarizing layer 572 is disposed on the red color filter 568r, the black matrix 566 and the transparent layer 570 over the entire substrate 540.

The red color filter 568r is disposed to correspond to the red subpixel SPr, and the transparent layer 570 is disposed to correspond to an open area of the green and blue subpixels SPg and SPb.

For example, the red color filter 568r can include an organic material having a red pigment or a red dye and a relatively high transmittance, and the transparent layer 570 and the planarizing layer 572 can include an organic material having a relatively high transmittance. The transparent layer 570 can have a refractive index greater than a refractive index of the planarizing layer 572 such that the microlens ML functions as a convex lens.

The black matrix 566 and the red color filter 568r can have substantially the same thickness as each other. A thickness of the transparent layer 570 defined as a distance between an apex (a maximum point) of the semispherical shape of the microlens ML and a bottom surface of the transparent layer 570 can be greater than a thickness of each of the black matrix 566 and the red color filter 568r such that the microlens ML protrudes over the black matrix 566.

The transparent layer 570 of one body shape having the microlens ML on a top surface thereof can be formed through a forming step of an organic material layer, a coating step of a photoresist, an exposing step, a developing step, an etching step of the organic material layer and a heat treating step. The black matrix 566 can function as a sidewall that supports and divides the microlens ML for subpixels while the transparent layer 570 having the microlens ML is formed.

In the OLED display device according to a fifth embodiment of the present disclosure, a light extraction efficiency of the open area of the red, green and blue subpixels SPr, SPg and SPb is improved due to a microcavity effect according to adjustment of the distances between the first, second and third reflecting layers 544, 548 and 552 and the second electrode 562.

Since the second distance d2 between the second electrode 562 and the second reflecting layer 548 in the green subpixel SPg is greater than the third distance d3 between the second electrode 562 and the third reflecting layer 552 in the blue subpixel SPb and is smaller than the first distance d1 between the second electrode 562 and the first reflecting layer 544 in the red subpixel SPr (e.g., d1>d2>d3), the red colored light, the green colored light and the blue colored light of the emitting layer 560 are reflected between the second electrode 562 and the first, second and third reflecting layers 544, 548 and 552 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 568r is disposed in the open area of the red subpixel SPr, the light of the red main peak corresponding to a red color passes through the red color filter 568r, and the light of the red sub-peak corresponding to a color other than a red color is blocked or absorbed by the red color filter 568r such that a color purity is improved. Since the transparent layer 570 is disposed in the open area of each of the green and blue subpixels SPg and SPb instead of green and blue color filters, the lights of the green and blue main peaks corresponding to green and blue colors pass through the transparent layer 570 without a loss such that a luminance is improved.

Among the lights emitted from the open area and the non-open area of the red subpixel SPr, the light of the red main peak corresponding to a red color passes through the red color filter 568r to be emitted to an exterior, and the light of the red sub-peak corresponding to a color other than a red color is absorbed by the red color filter 568r not to be emitted to an exterior. The lights emitted from the non-open areas of the green and blue subpixels SPg and SPb are absorbed by the black matrix 566 not to be emitted to an exterior.

As a result, the lights of the sub-peaks of the non-open areas of the red, green and blue subpixels SPr, SPg and SPb are blocked, and a color purity and a color reproducibility are improved.

Since the microlens ML is disposed on the top surface of the transparent layer 570 of the green and blue subpixels SPg and SPb and the planarizing layer 572 is disposed on the microlens ML, a light extraction efficiency of the green colored light and the blue colored light of the green and blue subpixels SPg and SPb is improved and a subsequent process is easily performed.

In another embodiment, a microlens having an extended diameter can be disposed on a transparent layer.

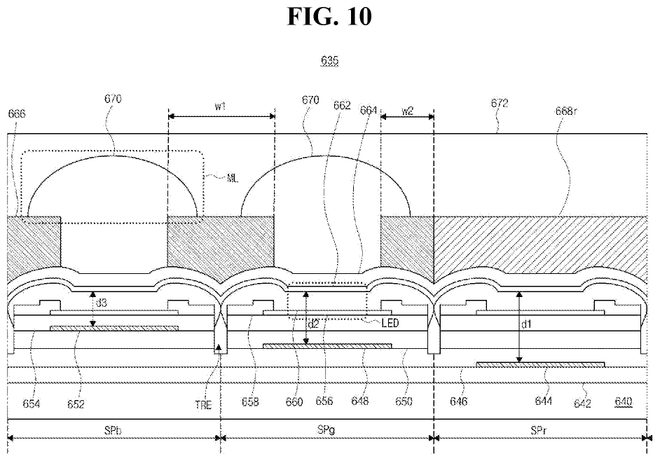

FIG. 10 is a cross-sectional view showing a display panel of an organic light emitting diode display device according to a sixth embodiment of the present disclosure. Illustration on a part of a sixth embodiment the same as that of first to fifth embodiments can be omitted. For example, each of the microlenses disposed in the blue and green subpixels SPb and SPg can be wider than the corresponding hole or opening in the black matrix 666 and wider than the corresponding emitting layer.

In FIG. 10, a display panel 635 of an organic light emitting diode display device according to a sixth embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 642, a first reflecting layer 644, a second insulating layer 646, a second reflecting layer 648, a third insulating layer 650, a third reflecting layer 652, a fourth insulating layer 654, a first electrode 656, a bank layer 658, an emitting layer 660, a second electrode 662 and an encapsulating layer 664 are sequentially disposed on a substrate 640.

A black matrix 666 is disposed in a border region between the red, green and blue subpixels SPr, SPg and SPb on the encapsulating layer 664. The black matrix 666 is disposed to correspond to a non-open area of the green and blue subpixels SPg and SPb and the black matrix 666 has a matrix shape covering an edge portion of each of the green and blue subpixels SPg and SPb and exposing the entire red subpixel SPr and a central portion of each of the green and blue subpixels SPg and SPb.

The black matrix 666 is not disposed in the red subpixel SPr of the border region between the red and green subpixels SPr and SPg and is disposed in the green subpixel SPg of the border region between the red and green subpixels SPr and SPg. The black matrix 666 is disposed in the green and blue subpixels SPg and SPb of the border region between the green and blue subpixels SPg and SPb. The black matrix 666 is disposed in the blue subpixel SPb of the border region between the blue and red subpixels SPb and SPr and is not disposed in the red subpixel SPr of the border region between the blue and red subpixels SPb and SPr.

The black matrix 666 is not disposed in the red subpixel SPr and is disposed in the green and blue subpixels SPg and SPb. As a result, a first width w1 of the black matrix 666 between the green and blue subpixels SPg and SPb can be greater than a second width w2 of the black matrix 666 between the red and green subpixels SPr and SPg and between the blue and red subpixels SPb and SPr (e.g., w1>w2).

For example, the black matrix 666 can include an organic insulating material or an inorganic insulating material having a relatively high absorbance and a relatively low transmittance, or the black matrix 666 can include an opaque metallic material such as molybdenum (Mo) and titanium (Ti).

A red color filter 668r is disposed on the encapsulating layer 664 in the red subpixel SPr, and a transparent layer 670 is disposed on the encapsulating layer 664 in each of the green and blue subpixels SPg and SPb between portions of the black matrix 666. A microlens ML of a semispherical shape having a diameter greater than a width of the transparent layer 670 is disposed on a top surface of the transparent layer 670 as one body with the transparent layer 670.

A light passing through the transparent layer 670 is concentrated on a front of the display panel 635 due to the microlens ML of the transparent layer 670 to improve a luminance. Since the microlens ML has a relatively great height to cover the adjacent black matrix 666, the microlens ML can have a relatively great curvature.

A planarizing layer 672 is disposed on the red color filter 668r, the black matrix 666 and the transparent layer 670 over the entire substrate 640.

The red color filter 668r is disposed to correspond to the red subpixel SPr, and the transparent layer 670 is disposed to correspond to an open area of the green and blue subpixels SPg and SPb.

For example, the red color filter 668r can include an organic material having a red pigment or a red dye and a relatively high transmittance, and the transparent layer 670 and the planarizing layer 672 can include an organic material having a relatively high transmittance. The transparent layer 670 can have a refractive index greater than a refractive index of the planarizing layer 672 such that the microlens ML functions as a convex lens.

The black matrix 666 and the red color filter 668r can have substantially the same thickness as each other. A thickness of the transparent layer 670 defined as a distance between an apex (a maximum point) of the semispherical shape of the microlens ML and a bottom surface of the transparent layer 670 can be greater than a thickness of each of the black matrix 666 and the red color filter 668r such that the microlens ML protrudes over the black matrix 666.

The transparent layer 670 of one body shape having the microlens ML on a top surface thereof can be formed through a forming step of an organic material layer, a coating step of a photoresist, an exposing step, a developing step, an etching step of the organic material layer and a heat treating step. The black matrix 666 can function as a sidewall that supports and divides the microlens ML for subpixels while the transparent layer 670 having the microlens ML.

In the OLED display device according to a sixth embodiment of the present disclosure, a light extraction efficiency of the open area of the red, green and blue subpixels SPr, SPg and SPb is improved due to a microcavity effect according to adjustment of the distances between the first, second and third reflecting layers 644, 648 and 652 and the second electrode 662.

Since the second distance d2 between the second electrode 662 and the second reflecting layer 648 in the green subpixel SPg is greater than the third distance d3 between the second electrode 662 and the third reflecting layer 652 in the blue subpixel SPb and is smaller than the first distance d1 between the second electrode 662 and the first reflecting layer 644 in the red subpixel SPr (e.g., d1>d2>d3), the red colored light, the green colored light and the blue colored light of the emitting layer 660 are reflected between the second electrode 662 and the first, second and third reflecting layers 644, 648 and 652 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 668r is disposed in the open area of the red subpixel SPr, the light of the red main peak corresponding to a red color passes through the red color filter 568r, and the light of the red sub-peak corresponding to a color other than a red color is absorbed by the red color filter 668r such that a color purity is improved. Since the transparent layer 670 is disposed in the open area of each of the green and blue subpixels SPg and SPb instead of green and blue color filters, the lights of the green and blue main peaks corresponding to green and blue colors pass through the transparent layer 670 without a loss such that a luminance is improved.

Among the lights emitted from the open area and the non-open area of the red subpixel SPr, the light of the red main peak corresponding to a red color passes through the red color filter 668r to be emitted to an exterior, and the light of the red sub-peak corresponding to a color other than a red color is absorbed by the red color filter 668r not to be emitted to an exterior. The lights emitted from the non-open areas of the green and blue subpixels SPg and SPb are absorbed by the black matrix 666 not to be emitted to an exterior.

As a result, the lights of the sub-peaks of the non-open areas of the red, green and blue subpixels SPr, SPg and SPb are blocked, and a color purity and a color reproducibility are improved.

Since the microlens ML is disposed on the top surface of the transparent layer 670 of the green and blue subpixels SPg and SPb and the planarizing layer 672 is disposed on the microlens ML, a light extraction efficiency of the green colored light and the blue colored light of the green and blue subpixels SPg and SPb is improved and a subsequent process is easily performed.

Since the microlens ML has a relatively great height to cover the adjacent black matrix 666, the microlens ML has a relatively great curvature and a concentration degree of a light on a front of the display panel 635 is improved. For example, since the microlens ML covers portions of the black matrix 666, the microlens ML can be made larger and have higher height and a greater radius of curvature, in which more light can be extracted outside of the device, which can improve luminance, and reduce power consumption.

In another embodiment, first and second microlenses can be disposed on a transparent layer and a red color filter, respectively.

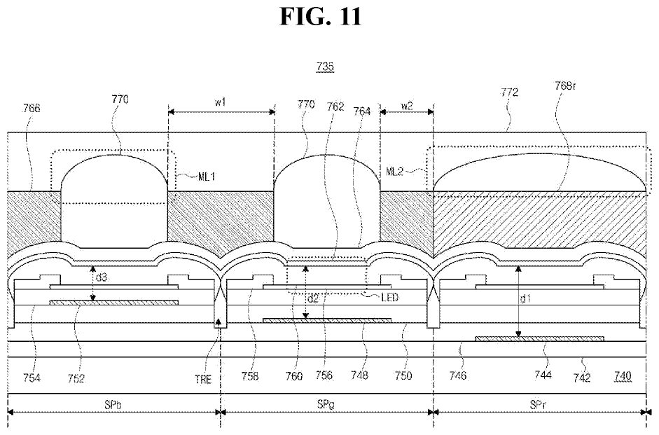

FIG. 11 is a cross-sectional view showing a display panel of an organic light emitting diode display device according to a seventh embodiment of the present disclosure. Illustration on a part of a seventh embodiment the same as that of first to sixth embodiments can be omitted.

In FIG. 11, a display panel 735 of an organic light emitting diode display device according to a seventh embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 742, a first reflecting layer 744, a second insulating layer 746, a second reflecting layer 748, a third insulating layer 750, a third reflecting layer 752, a fourth insulating layer 754, a first electrode 756, a bank layer 758, an emitting layer 760, a second electrode 762 and an encapsulating layer 764 are sequentially disposed on a substrate 740.

A black matrix 766 is disposed in a border region between the red, green and blue subpixels SPr, SPg and SPb on the encapsulating layer 764. The black matrix 766 is disposed to correspond to a non-open area of the green and blue subpixels SPg and SPb and the black matrix 766 has a matrix shape covering an edge portion of each of the green and blue subpixels SPg and SPb and exposing the entire red subpixel SPr and a central portion of each of the green and blue subpixels SPg and SPb.

The black matrix 766 is not disposed in the red subpixel SPr of the border region between the red and green subpixels SPr and SPg and is disposed in the green subpixel SPg of the border region between the red and green subpixels SPr and SPg. The black matrix 766 is disposed in the green and blue subpixels SPg and SPb of the border region between the green and blue subpixels SPg and SPb. The black matrix 766 is disposed in the blue subpixel SPb of the border region between the blue and red subpixels SPb and SPr and is not disposed in the red subpixel SPr of the border region between the blue and red subpixels SPb and SPr.

The black matrix 766 is not disposed in the red subpixel SPr and is disposed in the green and blue subpixels SPg and SPb. As a result, a first width w1 of the black matrix 766 between the green and blue subpixels SPg and SPb can be greater than a second width w2 of the black matrix 766 between the red and green subpixels SPr and SPg and between the blue and red subpixels SPb and SPr (e.g., w1>w2).

For example, the black matrix 766 can include an organic insulating material or an inorganic insulating material having a relatively high absorbance and a relatively low transmittance, or the black matrix 766 can include an opaque metallic material such as molybdenum (Mo) and titanium (Ti).

A red color filter 768r is disposed on the encapsulating layer 764 in the red subpixel SPr, and a transparent layer 770 is disposed on the encapsulating layer 764 in each of the green and blue subpixels SPg and SPb between portions of the black matrix 766. A first microlens ML1 of a semispherical shape having a diameter the same as a width of the transparent layer 770 is disposed on a top surface of the transparent layer 770 as one body with the transparent layer 770. A second microlens ML2 of a semispherical shape having a diameter the same as a width of the red color filter 768r is disposed on the red color filter 768r. For example, the second microlens ML2 in the red subpixel SPr can be larger than each of the micro lenses ML1 in the green and blue subpixels SPg and SPb. Also, the second microlens ML2 in the red subpixel SPr can have a same height or a same thickness as each of the micro lenses ML1 in the green and blue subpixels SPg and SPb, but the second microlens ML2 in the red subpixel SPr can be greater radius of curvature than each of the micro lenses ML1 in the green and blue subpixels SPg and SPb.

Since a width of the red color filter 768r is greater than a width of the transparent layer 770, the diameter of the second microlens ML2 can be greater than the diameter of the first microlens ML1.

Lights passing through the transparent layer 770 and the red color filter 768r are concentrated on a front of the display panel 735 due to the first microlens ML1 of the transparent layer 770 and the second microlens ML2 on the red color filter 768r to improve a luminance. The first and second microlenses ML1 and ML2 can include the same layer and the same material as each other.

A planarizing layer 772 is disposed on the red color filter 768r, the black matrix 766 and the transparent layer 770 over the entire substrate 740.

The red color filter 768r is disposed to correspond to the red subpixel SPr, and the transparent layer 770 is disposed to correspond to an open area of the green and blue subpixels SPg and SPb.

For example, the red color filter 768r can include an organic material having a red pigment or a red dye and a relatively high transmittance, and the transparent layer 770, the second microlens ML2 and the planarizing layer 772 can include an organic material having a relatively high transmittance. The transparent layer 770 and the second microlens ML2 can have a refractive index greater than a refractive index of the planarizing layer 772 such that the first and second microlenses ML1 and ML2 function as a convex lens.

The black matrix 766 and the red color filter 768r can have substantially the same thickness as each other. A thickness of the transparent layer 770 defined as a distance between an apex (a maximum point) of the semispherical shape of the first microlens ML1 and a bottom surface of the transparent layer 770 can be greater than a thickness of each of the black matrix 766 and the red color filter 768r such that the first microlens ML1 protrudes over the black matrix 766.

The transparent layer 770 of one body shape having the first microlens ML1 on a top surface thereof and the second microlens ML2 can be formed through a forming step of an organic material layer, a coating step of a photoresist, an exposing step, a developing step, an etching step of the organic material layer and a heat treating step. The black matrix 766 can function as a sidewall that supports and divides the first microlens ML1 for subpixels while the transparent layer 770 having the first microlens ML1 is formed.

In the OLED display device according to a seventh embodiment of the present disclosure, a light extraction efficiency of the open area of the red, green and blue subpixels SPr, SPg and SPb is improved due to a microcavity effect according to adjustment of the distances between the first, second and third reflecting layers 744, 748 and 752 and the second electrode 762.

Since the second distance d2 between the second electrode 762 and the second reflecting layer 748 in the green subpixel SPg is greater than the third distance d3 between the second electrode 762 and the third reflecting layer 752 in the blue subpixel SPb and is smaller than the first distance d1 between the second electrode 762 and the first reflecting layer 744 in the red subpixel SPr (e.g., d1>d2>d3), the red colored light, the green colored light and the blue colored light of the emitting layer 760 are reflected between the second electrode 762 and the first, second and third reflecting layers 744, 748 and 752 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 768r is disposed in the open area of the red subpixel SPr, the light of the red main peak corresponding to a red color passes through the red color filter 768r, and the light of the red sub-peak corresponding to a color other than a red color is absorbed by the red color filter 768r such that a color purity is improved. Since the transparent layer 770 is disposed in the open area of each of the green and blue subpixels SPg and SPb instead of green and blue color filters, the lights of the green and blue main peaks corresponding to green and blue colors pass through the transparent layer 770 without a loss such that a luminance is improved.

Among the lights emitted from the open area and the non-open area of the red subpixel SPr, the light of the red main peak corresponding to a red color passes through the red color filter 768r to be emitted to an exterior, and the light of the red sub-peak corresponding to a color other than a red color is absorbed by the red color filter 768r not to be emitted to an exterior. The lights emitted from the non-open areas of the green and blue subpixels SPg and SPb are absorbed by the black matrix 766 not to be emitted to an exterior.

As a result, the lights of the sub-peaks of the non-open areas of the red, green and blue subpixels SPr, SPg and SPb are blocked, and a color purity and a color reproducibility are improved.

The first microlens ML1 is disposed on the top surface of the transparent layer 770 of the green and blue subpixels SPg and SPb, the second microlens ML2 is disposed on the red color filter 768r of the red subpixel SPr, and the planarizing layer 772 is disposed on the first and second microlenses ML1 and ML2. As a result, a light extraction efficiency of the red colored light, the green colored light and the blue colored light of the red, green and blue subpixels SPr, SPg and SPb is improved and a subsequent process is easily performed.

In another embodiment, first and second microlenses of different materials can be disposed on a transparent layer and a red color filter, respectively.

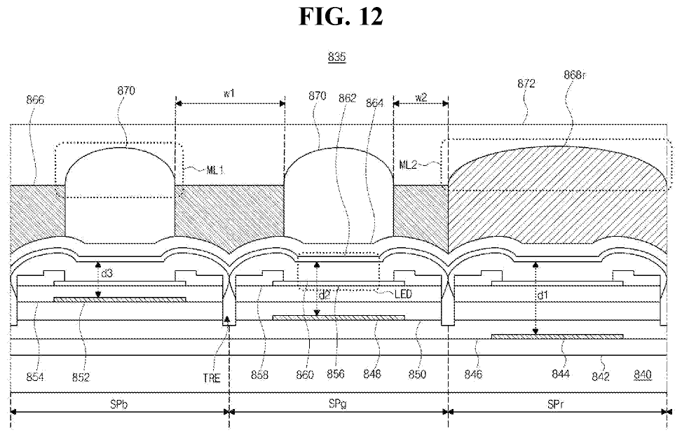

FIG. 12 is a cross-sectional view showing a display panel of an organic light emitting diode display device according to an eighth embodiment of the present disclosure. Illustration on a part of an eighth embodiment the same as that of first to seventh embodiments can be omitted.

In FIG. 12, a display panel 835 of an organic light emitting diode display device according to an eighth embodiment of the present disclosure includes red, green and blue subpixels SPr, SPg and SPb, and each of the red, green and blue subpixels SPr, SPg and SPb includes a plurality of thin film transistors and a light emitting diode LED.

A first insulating layer 842, a first reflecting layer 844, a second insulating layer 846, a second reflecting layer 848, a third insulating layer 850, a third reflecting layer 852, a fourth insulating layer 854, a first electrode 856, a bank layer 858, an emitting layer 860, a second electrode 862 and an encapsulating layer 864 are sequentially disposed on a substrate 840.

A black matrix 866 is disposed in a border region between the red, green and blue subpixels SPr, SPg and SPb on the encapsulating layer 864. The black matrix 866 is disposed to correspond to a non-open area of the green and blue subpixels SPg and SPb and the black matrix 866 has a matrix shape covering an edge portion of each of the green and blue subpixels SPg and SPb and exposing the entire red subpixel SPr and a central portion of each of the green and blue subpixels SPg and SPb.

The black matrix 866 is not disposed in the red subpixel SPr of the border region between the red and green subpixels SPr and SPg and is disposed in the green subpixel SPg of the border region between the red and green subpixels SPr and SPg. The black matrix 866 is disposed in the green and blue subpixels SPg and SPb of the border region between the green and blue subpixels SPg and SPb. The black matrix 866 is disposed in the blue subpixel SPb of the border region between the blue and red subpixels SPb and SPr and is not disposed in the red subpixel SPr of the border region between the blue and red subpixels SPb and SPr.

The black matrix 866 is not disposed in the red subpixel SPr and is disposed in the green and blue subpixels SPg and SPb. As a result, a first width w1 of the black matrix 866 between the green and blue subpixels SPg and SPb can be greater than a second width w2 of the black matrix 866 between the red and green subpixels SPr and SPg and between the blue and red subpixels SPb and SPr (e.g., w1>w2).

For example, the black matrix 866 can include an organic insulating material or an inorganic insulating material having a relatively high absorbance and a relatively low transmittance, or the black matrix 866 can include an opaque metallic material such as molybdenum (Mo) and titanium (Ti).

A red color filter 868r is disposed on the encapsulating layer 864 in the red subpixel SPr, and a transparent layer 870 is disposed on the encapsulating layer 864 in each of the green and blue subpixels SPg and SPb between portions of the black matrix 866. A first microlens ML1 of a semispherical shape having a diameter the same as a width of the transparent layer 870 is disposed on a top surface of the transparent layer 870 as one body with the transparent layer 870. A second microlens ML2 of a semispherical shape having a diameter the same as a width of the red color filter 868r is disposed on the red color filter 868r as one body with the red color filter 868r. For example, the red color filter 868r can have a same thickness as the transparent layer 870 in each of the blue and green subpixels SPb and SPg, but be wider than the transparent layer 870 in each of the blue and green subpixels SPb and SPg.

Since a width of the red color filter 868r is greater than a width of the transparent layer 870, the diameter of the second microlens ML2 can be greater than the diameter of the first microlens ML1.

Lights passing through the transparent layer 870 and the red color filter 868r are concentrated on a front of the display panel 835 due to the first microlens ML1 of the transparent layer 870 and the second microlens ML2 of the red color filter 868r to improve a luminance.

A planarizing layer 872 is disposed on the red color filter 868r, the black matrix 866 and the transparent layer 870 over the entire substrate 840.

The red color filter 868r is disposed to correspond to the red subpixel SPr, and the transparent layer 870 is disposed to correspond to an open area of the green and blue subpixels SPg and SPb.

For example, the red color filter 868r can include an organic material having a red pigment or a red dye and a relatively high transmittance, and the transparent layer 870 and the planarizing layer 872 can include an organic material having a relatively high transmittance. The transparent layer 870 and the red color filter 868r can have a refractive index greater than a refractive index of the planarizing layer 872 such that the first and second microlenses ML1 and ML2 function as a convex lens.

A thickness of the transparent layer 870 defined as a distance between an apex (a maximum point) of the semispherical shape of the first microlens ML1 and a bottom surface of the transparent layer 870 and a thickness of the red color filter 868r defined as a distance between an apex (a maximum point) of the semispherical shape of the second microlens ML2 can be greater than a thickness of the black matrix 866 such that the first and second microlenses ML1 and ML2 protrude over the black matrix 866.

The transparent layer 870 of one body shape having the first microlens ML1 on a top surface thereof can be formed through a forming step of an organic material layer, a coating step of a photoresist, an exposing step, a developing step, an etching step of the organic material layer and a heat treating step. The black matrix 866 can function as a sidewall that supports and divides the first microlens ML1 for subpixels while the transparent layer 870 having the first microlens ML1 is formed.

The red color filter 868r of one body shape having the second microlens ML2 on a top surface thereof can be formed through a coating step of a color filter material, an exposing step, a developing step and a heat treating step. The black matrix 866 can function as a sidewall that supports and divides the second microlens ML2 for subpixels while the transparent layer 870 having the second microlens ML2 is formed.

In the OLED display device according to an eighth embodiment of the present disclosure, a light extraction efficiency of the open area of the red, green and blue subpixels SPr, SPg and SPb is improved due to a microcavity effect according to adjustment of the distances between the first, second and third reflecting layers 844, 848 and 852 and the second electrode 862.

Since the second distance d2 between the second electrode 862 and the second reflecting layer 848 in the green subpixel SPg is greater than the third distance d3 between the second electrode 862 and the third reflecting layer 852 in the blue subpixel SPb and is smaller than the first distance d1 between the second electrode 862 and the first reflecting layer 844 in the red subpixel SPr (e.g., d1>d2>d3), the red colored light, the green colored light and the blue colored light of the emitting layer 860 are reflected between the second electrode 862 and the first, second and third reflecting layers 844, 848 and 852 in the red, green and blue subpixels SPr, SPg and SPb to be constructively interfered. As a result, the light extraction efficiency and the luminance of the red colored light, the green colored light and the blue colored light of the red, green and blue subpixels SPr, SPg and SPb are improved.

Due to the microcavity effect, the light emitted from the open area of the red subpixel SPr has a red main peak corresponding to a red color and a red sub-peak corresponding to a color other than the red color, while the lights emitted from the open areas of the green and blue subpixels SPg and SPb have green and blue main peaks corresponding to green and blue colors, respectively.

Since the red color filter 868r is disposed in the open area of the red subpixel SPr, the light of the red main peak corresponding to a red color passes through the red color filter 868r, and the light of the red sub-peak corresponding to a color other than a red color is absorbed by the red color filter 868r such that a color purity is improved. Since the transparent layer 870 is disposed in the open area of each of the green and blue subpixels SPg and SPb instead of green and blue color filters, the lights of the green and blue main peaks corresponding to green and blue colors pass through the transparent layer 870 without a loss such that a luminance is improved.

Among the lights emitted from the open area and the non-open area of the red subpixel SPr, the light of the red main peak corresponding to a red color passes through the red color filter 868r to be emitted to an exterior, and the light of the red sub-peak corresponding to a color other than a red color is absorbed by the red color filter 868r not to be emitted to an exterior. The lights emitted from the non-open areas of the green and blue subpixels SPg and SPb are absorbed by the black matrix 866 not to be emitted to an exterior.

As a result, the lights of the sub-peaks of the non-open areas of the red, green and blue subpixels SPr, SPg and SPb are blocked, and a color purity and a color reproducibility are improved.

The first microlens ML1 is disposed on the top surface of the transparent layer 870 of the green and blue subpixels SPg and SPb, the second microlens ML2 is disposed on the red color filter 868r of the red subpixel SPr, and the planarizing layer 872 is disposed on the first and second microlenses ML1 and ML2. As a result, a light extraction efficiency of the red colored light, the green colored light and the blue colored light of the red, green and blue subpixels SPr, SPg and SPb is improved and a subsequent process is easily performed.

Consequently, in the OLED display device according to embodiments of the present disclosure, since the black matrix having different widths is disposed to correspond to the non-open area and the color filter is selectively disposed to correspond to the open area, the light of the sub-peak of the non-open area is blocked. As a result, the color purity and the color reproducibility are improved and the efficiency and the luminance are improved.

Further, since the black matrix having different widths is disposed to correspond to the non-open area and the microlens is disposed to correspond to the open area, the light of the sub-peak of the non-open area is blocked. As a result, the color purity and the color reproducibility are improved and the fabrication process is stabilized.

It will be apparent to those skilled in the art that various modifications and variation can be made in the present disclosure without departing from the scope of the disclosure. Thus, it is intended that the present disclosure cover the modifications and variations of this disclosure, provided they come within the scope of the appended claims and their equivalents.

What is claimed is:

1. An organic light emitting diode display device, comprising:
first, second and third subpixels disposed on a substrate;
first, second and third light emitting diodes disposed in the first, second and third subpixels, respectively;
a black matrix disposed in boarder regions of the second subpixel and the third subpixel;
a first color filter disposed in the first subpixel and overlapping with the first light emitting diode; and
a transparent layer disposed in at least one of the second and third subpixels between portions of the black matrix.

2. The organic light emitting diode display device of claim 1, wherein the first subpixel excludes any portion of the black matrix.

3. The organic light emitting diode display device of claim 1, wherein a first width of a first portion of the black matrix disposed between the second and third subpixels is greater than a second width of a second portion of the black matrix disposed between the first and second subpixels.

4. The organic light emitting diode display device of claim 1, further comprising:
first, second and third reflecting layers respectively disposed between first, second and third light emitting diodes and the substrate,
wherein each of the first, second and third light emitting diodes includes a first electrode, an emitting layer and a second electrode sequentially on the substrate, and
wherein a first distance between the first reflecting layer and the second electrode in the first subpixel is greater than a second distance between the second reflecting layer and the second electrode in the second subpixel, and the second distance between the second reflecting layer and the second electrode in the second subpixel is greater than a third distance between the third reflecting layer and the second electrode in the third subpixel.

5. The organic light emitting diode display device of claim 1, further comprising a third color filter disposed in the third subpixel between portions of the black matrix.

6. The organic light emitting diode display device of claim 1, wherein the black matrix is disposed in the first subpixel and in border regions between the first, second and third subpixels.

7. The organic light emitting diode display device of claim 1, wherein the transparent layer covers the black matrix and the first color filter to planarize the black matrix and the first color filter.

8. The organic light emitting diode display device of claim 1, further comprising:
a first microlens on a top surface of the transparent layer; and
a planarizing layer disposed on the first microlens.

9. The organic light emitting diode display device of claim 8, wherein a diameter of the first microlens is equal to or greater than a width of the transparent layer.

10. The organic light emitting diode display device of claim 8, further comprising a second microlens on the first color filter,
wherein the second microlens includes a same material as the transparent layer.

11. The organic light emitting diode display device of claim 1, further comprising:
a first microlens on a top surface of the transparent layer;
a second microlens on a top surface of the first color filter; and
a planarizing layer disposing on the first and second microlenses.

12. The organic light emitting diode display device of claim 1, further comprising:
a first trench disposed between the first subpixel and the second subpixel;
a second trench disposed between the second subpixel and the third subpixel; and
an emitting layer disposed in the first, second and third subpixels,
wherein a portion of the emitting layer overlapping with the first trench or the second trench is thinner than a portion of the emitting layer overlapping with a center of at least one of the first, second and third subpixels, or the emitting layer is disconnected by at least one of the first trench and the second trench.

13. The organic light emitting diode display device of claim 1, wherein a first portion of the black matrix is disposed between a center of the first trench and the second subpixel, and an area between the center of the first trench and the first subpixel does not include any portion of the black matrix.

14. The organic light emitting diode display device of claim 13, wherein a second portion of the black matrix overlaps with a center of the second trench between the second subpixel and the third subpixel.

15. The organic light emitting diode display device of claim 1, wherein portions of the black matrix surrounding four sides of the third subpixel have a first width in a plan view,
wherein portions of the black matrix surrounding three sides of the second subpixel have the first width and a portion of the black matrix surrounding one side of the second subpixel has a second width that is less than the first width in the plan view, and
wherein two portions of the black matrix surrounding two opposites of the first subpixel have the first width in the plan view.

16. A display device, comprising:
first, second and third subpixels disposed on a substrate;
first, second and third light emitting layers disposed in the first, second and third subpixels, respectively;
a first black matrix portion disposed between the first subpixel and the second subpixel; and
a second black matrix portion disposed between the second subpixel and the third subpixel,
wherein a first width of the first black matrix portion between the first subpixel and the second subpixel is less than a second width of the second black matrix portion between the second subpixel and the third subpixel.

17. The display device of claim 16, further comprising:
a trench surrounding each of the first, second and third subpixels,
wherein the trench is configured to disconnect or thin a portion of the first, second and third light emitting layers.

18. The display device of claim 16, further comprising:
first, second and third reflecting layers overlapping with the first, second and third light emitting layers, respectively,
wherein a first distance between the first reflecting layer and the first light emitting layer in the first subpixel is greater than a second distance between the second reflecting layer and the second light emitting layer in the second subpixel, and the second distance between the second reflecting layer and the second light emitting layer in the second subpixel is greater than a third distance between the third reflecting layer and the third light emitting layer in the third subpixel.

19. The display device of claim 16, further comprising:
a color filter disposed in the first subpixel,
wherein at least one of the second subpixel and the third subpixel does not include any color filter.

20. The display device of claim 16, further comprising:
a microlens disposed in at least one of first, second and third subpixels.

21. The display device of claim 16, wherein the first subpixel is not overlapped by any portion of a black matrix.
